(19) United States
(12) Patent Application Publication
(10) Pub. No.: US 2015/0243638 A1
(43) Pub. Date: Aug. 27, 2015

(54) SEMICONDUCTOR DEVICE

(71) Applicant: KABUSHIKI KAISHA TOSHIBA, Tokyo (JP)

(72) Inventor: Nobutaka MATSUOKA, Kanzaki Hyogo (JP)

(21) Appl. No.: 14/474,057

(22) Filed: Aug. 29, 2014

(30) Foreign Application Priority Data
Feb. 27, 2014 (JP) 2014-037564

(51) Int. Cl. H01L 25/07; H01L 23/48; H01L 21/768; H01L 23/04; H01L 23/538; H01L 25/00; H01L 23/31; H01L 23/29

(52) U.S. Cl. CPC H01L 25/074; H01L 23/3107; H01L 23/481; H01L 23/293; H01L 23/04; H01L 23/5386; H01L 25/50; H01L 21/76898; H01L 2225/06541; H01L 2225/06548

(57) ABSTRACT

According to one embodiment, a semiconductor device includes a semiconductor chip, a package that surrounds the semiconductor chip, a first electrode terminal of which an upper end portion is aligned with and exposed at an upper surface of the package or protrudes from the upper surface of the package on an upper side of the package, and of which a lower end portion is aligned with and exposed at a lower surface of the package, or protrudes from the lower surface of the package on a lower side of the package, and a second electrode terminal of which an upper end portion is aligned with and exposed at the upper surface of the package, or protrudes from the upper surface of the package on the upper side of the package, and of which a lower end portion is aligned with and exposed at the lower surface of the package or protrudes from the lower surface of the package on the lower side of the package.

### CROSS-REFERENCE TO RELATED APPLICATION

This application is based upon and claims the benefit of priority from Japanese Patent Application No. 2014-037564, filed Feb. 27, 2014, the entire contents of which are incorporated herein by reference.

### FIELD

Embodiments described herein relate generally to a semiconductor device.

### BACKGROUND

For example, in a packaged semiconductor device, one or more semiconductor devices such as a transistor, a diode or the like formed on a semiconductor chip is mounted on to a substrate. In order to make the packaged semiconductor device system small, it is preferable to reduce the area required for a wiring between the semiconductor devices.

### DESCRIPTION OF THE DRAWINGS

FIGS. 1A and 1B are schematic views of a semiconductor device according to a first embodiment.

FIG. 2 is a schematic perspective view of the semiconductor device according to the first embodiment.

FIGS. 3A and 3B are explanatory views of an operation of the semiconductor device according to the first embodiment.

FIGS. 4A and 4B are explanatory views of the operation of the semiconductor device according to the first embodiment.

FIG. 5 is a schematic perspective view of the semiconductor device according to a modification example of the first embodiment.

FIGS. 6A and 6B are schematic views of the semiconductor device according to a second embodiment.

FIGS. 7A and 7B are schematic views of the semiconductor device according to a third embodiment.

FIGS. 8A and 8B are schematic views of the semiconductor device according to a fourth embodiment.

FIGS. 9A and 9B are schematic views of the semiconductor device according to a fifth embodiment.

FIGS. 10A and 10B are schematic views of the semiconductor device according to a sixth embodiment.

FIGS. 11A and 11B are schematic views of the semiconductor device according to a seventh embodiment.

FIG. 12 is a schematic view of the semiconductor device according to an eighth embodiment.

FIG. 13 is a schematic view of the semiconductor device according to a ninth embodiment.

FIG. 14 is a schematic view of the semiconductor device according to a tenth embodiment.

FIG. 15 is a schematic perspective view of the semiconductor device according to an eleventh embodiment.

FIGS. 16A and 16B are schematic perspective views of a semiconductor system which has the semiconductor device according to the eleventh embodiment.

FIG. 17 is a schematic perspective view of the semiconductor system which has the semiconductor device according to the eleventh embodiment.

FIG. 18 is a schematic perspective view of the semiconductor device according to a twelfth embodiment.

FIG. 19 is a schematic perspective view of the semiconductor system which has the semiconductor device according to the thirteenth embodiment.

FIG. 20 is a schematic perspective view of a modification example of the semiconductor system which has the semiconductor device according to the thirteenth embodiment.

FIGS. 21A and 21B are schematic views of the semiconductor system according to a fourteenth embodiment.

FIGS. 22A and 22B are schematic views of the semiconductor system according to the fourteenth embodiment.

### DETAILED DESCRIPTION

An exemplary embodiment herein provides a semiconductor device mountable on a secondary substrate, which results in a small semiconductor system on a secondary substrate in which a plurality of semiconductor devices is mounted.

In general, according to one embodiment, a semiconductor device includes: a semiconductor chip; a package that surrounds the semiconductor chip; a first electrode terminal of which an upper end portion is aligned with an upper surface of the package or protrudes from the upper surface of the package on an upper side of the package, and of which a lower end portion is aligned with a lower surface of the package or protrudes from the lower surface of the package on a lower side of the package; and a second electrode terminal of which an upper end portion is aligned with the upper surface of the package or protrudes from the upper surface of the package on the upper side of the package, and of which a lower end portion is aligned with the lower surface of the package or protrudes from the lower surface of the package on the lower side of the package. The semiconductor devices are modular, in that the structure thereof enables stacking and lateral connecting and packing thereof.

Hereinafter, embodiments will be described with reference to drawings. In the description below, the same or equivalent elements are referenced by the same reference numerals and the descriptions of the elements will not be repeated.

In the exemplary embodiments, “semiconductor chip” represents an active element(s) which uses a semiconductor as a material thereof. Examples of the active elements include diodes, transistors, thyristors, or the like.

In addition, in the exemplary embodiments, a “package” or packaging represents a member which is provided in the vicinity of the semiconductor chip and protects the semiconductor chip from physical shock, moisture, or the like. For example, materials, such as resins, silicon gels, and ceramics, or mixtures thereof may be adapted to form a part or all of the package.

In addition, in the exemplary embodiments, terms, such as “upper side”, “lower side”, “upper surface”, “lower surface”, “upper part”, “lower part” or the like, do not necessarily represent up and down with respect to a gravity direction. The terms are used in order to define a relative positional relationship of the members or the like.

In addition, in the exemplary embodiments, “semiconductor system” represents a semiconductor circuit in which a plurality of packaged semiconductor devices are mounted on a circuit substrate, such as a printed circuit substrate, or on a semiconductor module, or on another semiconductor circuit mounted on a printed circuit substrate, or on a semiconductor module. In the semiconductor system, in addition to the semiconductor device, passive components, such as a resistors and a capacitors, can be mounted.

### First Embodiment

The semiconductor device according to the embodiment includes: a semiconductor chip; a package which surrounds the semiconductor chip; a first electrode terminal of which an upper end portion is aligned with an upper surface of the package, or protrudes from the upper surface of the package on an upper side of the package and is thus exposed, and of which a lower end portion is aligned with a lower surface of the package, or protrudes from the lower surface of the package on a lower side of the package and is thus exposed; and a second electrode terminal of which an upper end portion is aligned with the upper surface of the package, or protrudes from the upper surface of the package on the upper side of the package and is thus exposed, and of which a lower end portion is aligned with the lower surface, or protrudes from the lower surface of the package on the lower side of the package and is thus exposed. Individual semiconductor devices may thus be interconnected via the exposed electrodes.

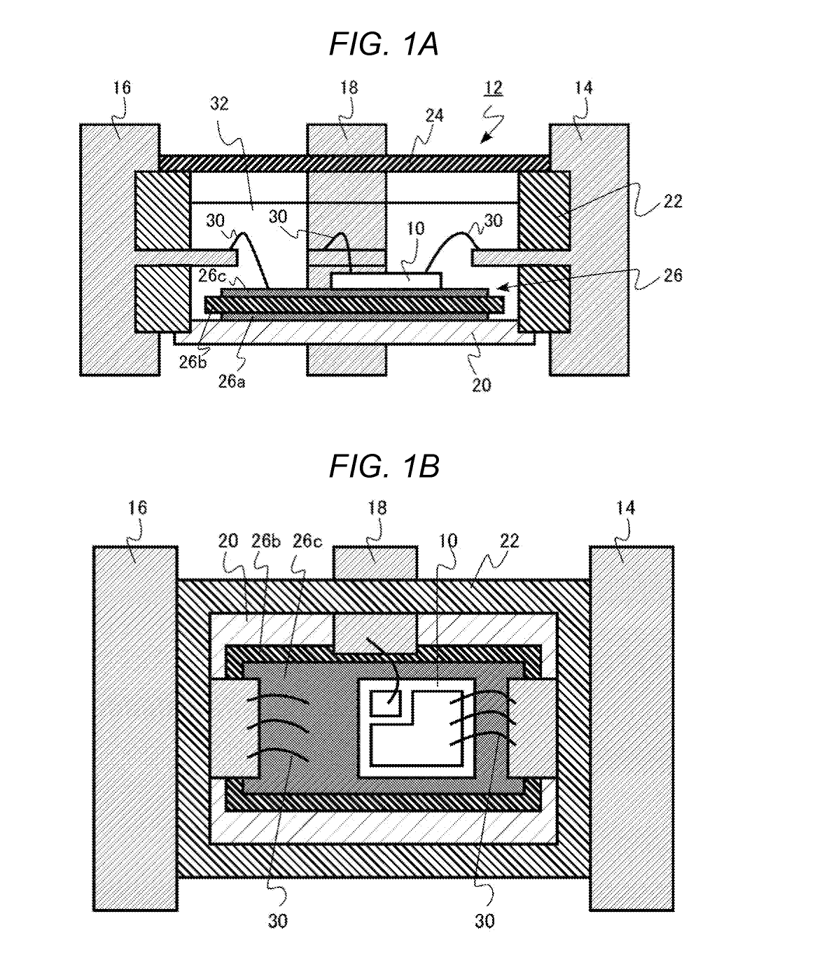

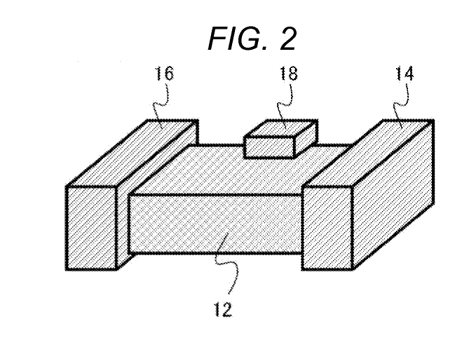

FIGS. 1A and 1B are schematic views of the semiconductor device according to the embodiment. FIG. 1A is a schematic cross-sectional view. FIG. 1B is a schematic top view. FIG. 1B is a view of a state where a protective material that covers a resin cap of an upper part of the semiconductor chip and the semiconductor chip have been removed. FIG. 2 is a schematic perspective view showing an outer appearance of the semiconductor device according to the embodiment.

The semiconductor device according to the embodiment is, for example, a vertical insulated gate bipolar transistor (IGBT) with three terminals. The semiconductor device according to the embodiment includes a semiconductor chip 10, a package 12, an emitter terminal (first electrode terminal) 14, a collector terminal (second electrode terminal) 16, and a gate terminal (third electrode terminal) 18.

The semiconductor chip 10 uses, for example, silicon or doped silicon, as the base material thereof. In the semiconductor chip 10, the vertical IGBT is formed.

The package 12 of the embodiment surrounds the semiconductor chip 10, and has a heat radiation plate 20 disposed below, and spaced from, the semiconductor chip 10, a resin case 22 spaced from, and surrounding, the semiconductor chip 10, and a resin cap 24 spaced from, and disposed above, an upper part of the semiconductor chip 10. The heat radiation plate 20 is made of, for example, metal, such as copper or aluminum. The heat radiation plate 20, the resin case 22 surrounding the semiconductor chip 10, and the resin cap 24 together encapsulate the semiconductor chip to provide protection thereof against the egress of moisture, physical shock, etc.

An insulation substrate 26 is provided on the heat radiation plate 20. The semiconductor chip 10 is mounted on the insulation substrate 26. The insulation substrate 26 has a three-layered structure including a conductive layer 26a, an insulation layer 26b, and a conductive layer 26c which is in electrical contact with the collector 16 of the semiconductor chip 16. The conductive layer 26a and the conductive layer 26c are made of, for example, metal such as copper. In addition, the insulation layer 26b is made of, for example, a ceramic such as alumina, aluminum nitride.

Each of the emitter electrode 14, collector electrode 16 and gate electrode are mounted at a periphery of the device 12, such that an upper and a lower surface thereof extend above and below the surface of the encapsulating portion of the chip, i.e., above and below the envelope formed by the heat radiation plate 20, the resin case 22 surrounding the semiconductor chip 10, and the resin cap 24. Thus an upper end portion of the emitter terminal 14 is aligned with an upper surface of the package 12, or protrudes from and is exposed above the upper surface of the package 12 on an upper side of the package 12. In the embodiment, the upper end portion of the emitter terminal 14 protrudes from an upper surface of the resin cap 24.

A lower end portion of the emitter terminal 14 is aligned with a lower surface of the package 12, or from the lower surface of the package 12 on a lower side of the package 12 and is there exposed. In the embodiment, the lower end portion of the emitter terminal 14 extends below the lower surface of the heat radiation plate 20.

The emitter terminal 14 is connected with an emitter electrode of the semiconductor chip 10, within the encapsulating envelope formed by the heat radiation plate 20, the resin case 22 surrounding the semiconductor chip 10, and the resin cap 24, by one or more bonding wires 30. The bonding wire 30 is made of metal, for example, a gold or aluminum wire.

An upper end portion of the collector terminal 16 is aligned with the upper surface of the package 12, or protrudes from the upper surface of the package 12 on the upper side of the package 12. In the embodiment, the upper end portion of the collector terminal 16 protrudes from the upper surface of the resin cap 24.

A lower end portion of the collector terminal 16 is aligned with the lower surface of the package 12, or protrudes from the lower surface of the package 12 on the lower side of the package 12. In the embodiment, the lower end portion of the collector terminal 16 protrudes below the lower surface of the heat radiation plate 20.

The collector terminal 16 is connected with a collector electrode of the semiconductor chip 10, within the encapsulating envelope formed by the heat radiation plate 20, the resin case 22 surrounding the semiconductor chip 10, and the resin cap 24, via the conductive layer 26c by one or more bonding wires 30. The bonding wire 30 is made of metal, for example, gold or aluminum wire.

An upper end portion of the gate terminal 18 is aligned with the upper surface of the package 12, or protrudes to be exposed above, the upper surface of the package 12 on the upper side of the package 12. In the embodiment, the upper end portion of the gate terminal 18 protrudes, and is thus exposed, above the upper surface of the resin cap 24.

A lower end portion of the gate terminal 18 is aligned with the lower surface of the package 12, or protrudes and is thus exposed below, the lower surface of the package 12 on the lower side of the package 12. In the embodiment, the lower end portion of the gate terminal 18 protrudes from the lower surface of the heat radiation plate 20.

The gate terminal 18 is connected with a gate electrode of the semiconductor chip 10, within the encapsulating envelope formed by the heat radiation plate 20, the resin case 22 surrounding the semiconductor chip 10, and the resin cap 24, by the bonding wire 30. The bonding wire 30 is made of metal, for example, such as gold or aluminum wire.

The semiconductor chip 10 is sealed, for example, by a silicon gel 32 within the envelope of the package 12 formed by the heat radiation plate 20, the resin case 22 surrounding the semiconductor chip 10, and the resin cap 24. The silicone gel 32 is a protective material for the semiconductor chip 10. The space between the upper surface of the silicone gel 32 and the underside of the resin cap 24 is hollow, i.e., a gap exists between the portion of the silicone gel overlying the semiconductor chip 10 and the underside of the resin cap 24.

In the semiconductor device according to the embodiment, the emitter terminal 14 and the collector terminal 16 are exposed on opposed sides of the package 12. The emitter terminal 14 and the collector terminal 16 are disposed along a side surface of the package 12, or protrude and are thus exposed at or outwardly of the side surfaces of the package 12.

Hereinafter, an operation and an effect of a semiconductor device according to the embodiment will be described.

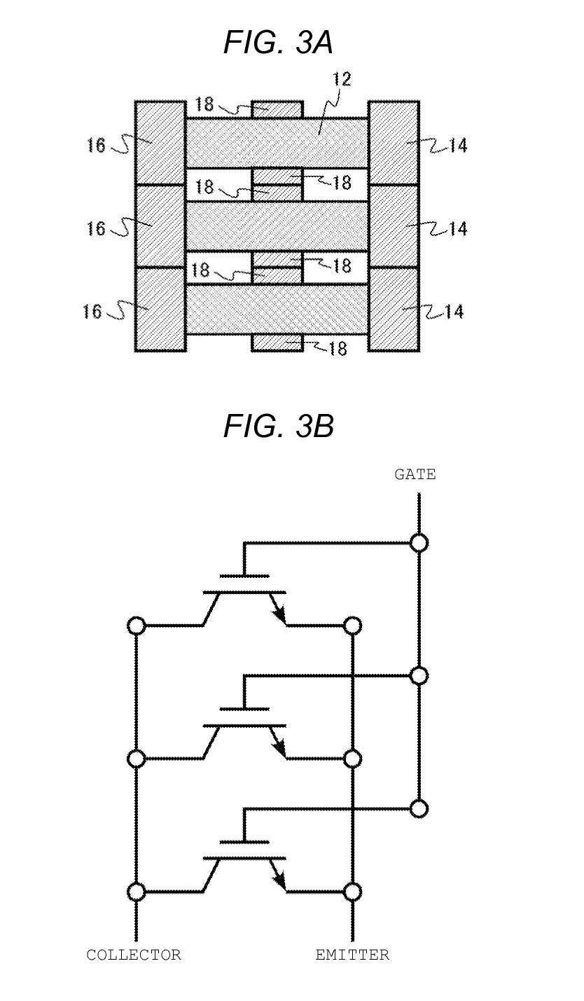

FIGS. 3A and 3B are explanatory views of the operation of the semiconductor device according to the embodiment. FIG. 3A is a view showing a configuration which combines a plurality of semiconductor devices according to the embodiment. FIG. 3B is a circuit diagram of the FIG. 3A.

In FIGS. 3A and 3B, the IGBTs according to the embodiment are vertically stacked as three layers thereof. In each of the IGBTs, the emitter terminal 14, the collector terminal 16, and the gate terminal 18 protrude from the upper surface and the lower surface of the package 12. Therefore, only by contacting terminals of vertically laminated IGBTs, electric conduction of each of the terminals is enabled. By vertically stacking the three IGBTs, as shown in FIG. 3B, a circuit which connects the three IGBTs in parallel is achieved.

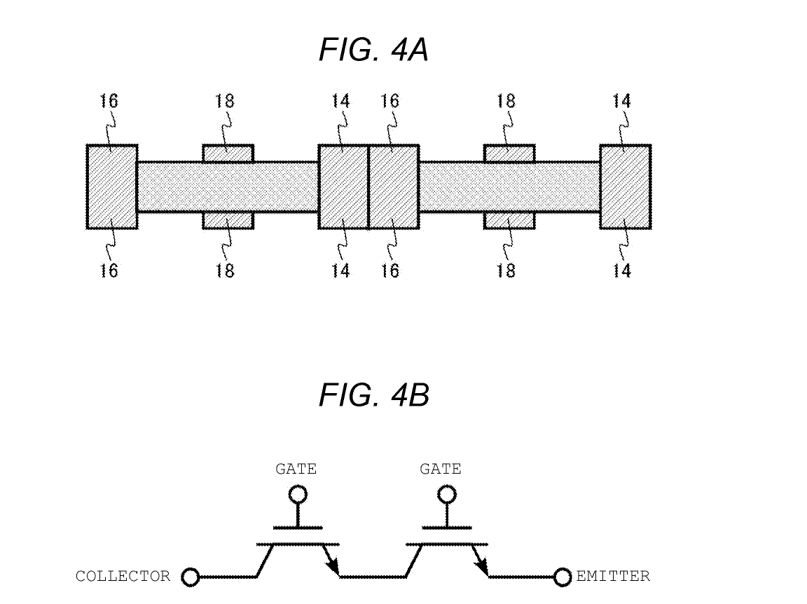

FIGS. 4A and 4B are views describing the operation of the semiconductor device according to the embodiment. FIG. 4A is a view showing a configuration which combines the semiconductor devices according to the embodiment. FIG. 4B is a circuit diagram of FIG. 4A.

In FIG. 4A, two IGBTs according to the embodiment are horizontally arranged. In each of the IGBTs, the emitter terminal 14 and the collector terminal 16 protrude from the side surfaces of the package 12. Therefore, only by contacting the terminals of a right IGBT and a left IGBT, the electric connection of each of the terminals is ensured. By arranging the two IGBTs horizontally, as shown in FIG. 4B, a circuit which connects the two IGBTs in series is achieved.

In the IGBTs according to the embodiment, the terminals protrude from the upper surface, the lower surface, and the side surface of the package 12. Accordingly, when the plurality of IGBTs are vertically stacked, or when the plurality of IGBTs are horizontally connected together, additional interconnection wiring is not required, and it is possible to easily connect the terminal of IGBTs with each other. In addition, as shown in FIGS. 3A and 3B and in FIGS. 4A and 4B, it is possible to connect the IGBTs in three dimensions. Therefore, it is possible to make the size of the resulting semiconductor system, incorporating multiple IGBT's, small.

In addition, when the IGBTs are vertically stacked, or when the IGBTs are horizontally arranged, the number of IGBTs is appropriately chosen. By doing this, it is possible to easily set a rated current or a rated voltage to a predetermined value. Therefore, a degree of design freedom of the semiconductor system is improved.

In addition, the electric conduction between terminals of each IGBT can be achieved by welding each pair of terminals by pressing them together under pressure. In addition, an adhesive layer, such as a soldering layer can be provided between each terminal.

### Modification Example

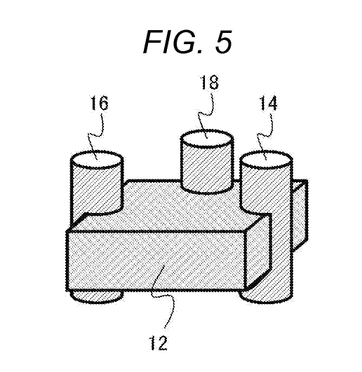

FIG. 5 is a schematic perspective view showing an outer appearance of the semiconductor device according to a modification example of the embodiment. The semiconductor device of the modification example has a different terminal shape from the semiconductor device according to the embodiment.

In the IGBT of the modification example, the emitter terminal 14, the collector terminal 16, and the gate terminal 18 are shown having a cylindrical shape. Even according to the semiconductor device of the modification example, similarly to the embodiment, it is possible to make the size of the semiconductor system small.

### Second Embodiment

The semiconductor device according to the embodiment is similar to the semiconductor device according to the first embodiment except the fact that the protective material of the semiconductor chip is molded resin and the heat radiation plate is not provided. Therefore, the portion of the same description as the first embodiment will not be repeated.

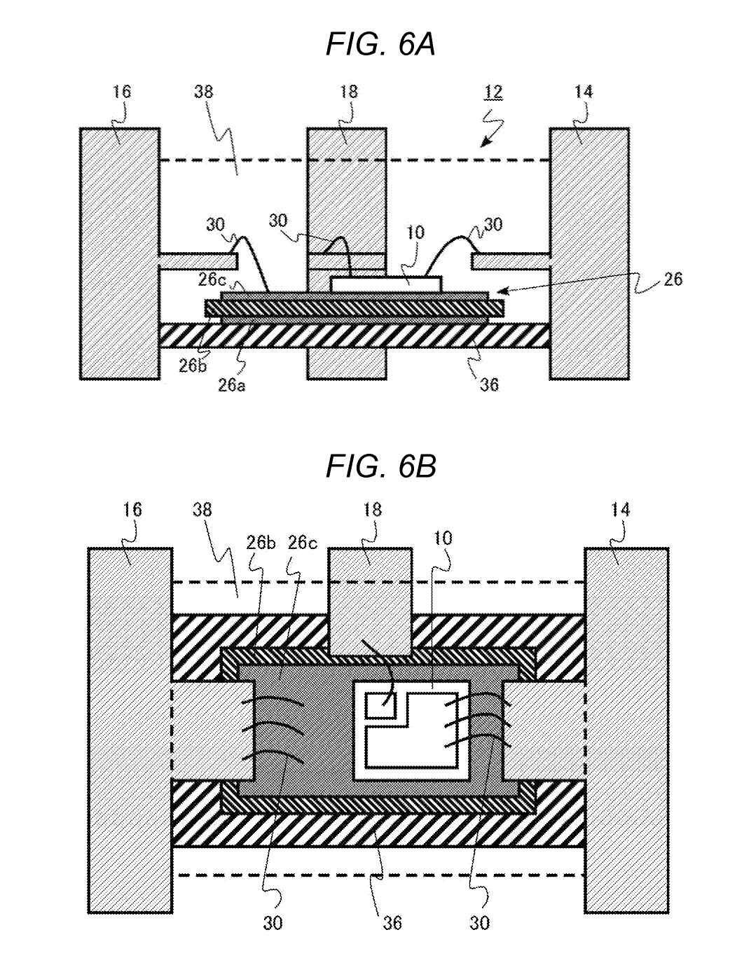

FIGS. 6A and 6B are schematic views of the semiconductor device according to the embodiment. FIG. 6A is a schematic cross-sectional view. FIG. 6B is a schematic top view. FIG. 6B is a view showing a state where the protective material on the upper part of the semiconductor chip is removed.

The package 12 according to the embodiment surrounds the semiconductor chip 10. The package 12 includes a supporting substrate 36 located below a lower part of the semiconductor chip 10 and a molding resin 38, molded over the chip and on exposed surfaces of the supporting substrate 36 adjacent the chip 10 mounting location thereon, used as the protective material of the semiconductor chip 10. The supporting substrate 36 is an insulator, for example, a resin or ceramic.

On the supporting substrate 36, the insulation substrate 26 is provided between the semiconductor chip 10 and the supporting substrate 36. The insulation substrate 26 has a three-layered structure including the conductive layer 26a, the insulation layer 26b, and the conductive layer 26c. The conductive layer 26a and the conductive layer 26c are made of, for example, copper. In addition, the insulation layer 26b is made of, for example, ceramics such as alumina, aluminum nitride.

The emitter, collector and gate terminals 14, 16 18 of the IGBTs according to the embodiment, similarly to the first embodiment, protrude from the upper surface, the lower surface, and the side surfaces of the package 12 comprised of the resin material and supporting substrate 36. Therefore, for example, when the semiconductor system in which the plurality of IGBTs is mounted on the printed circuit substrate is constructed, it is possible to make the size of the semiconductor system small.

In addition, compared to the first embodiment, use of smaller number of components and easy manufacturing are possible.

### Third Embodiment

The semiconductor device according to the embodiment is similar to the second embodiment except the fact that the semiconductor chip is directly connected with each terminal or a conductive layer, not by a bonding wire, but by an adhesive layer. Therefore, a part of the same description as the second embodiment will not be repeated.

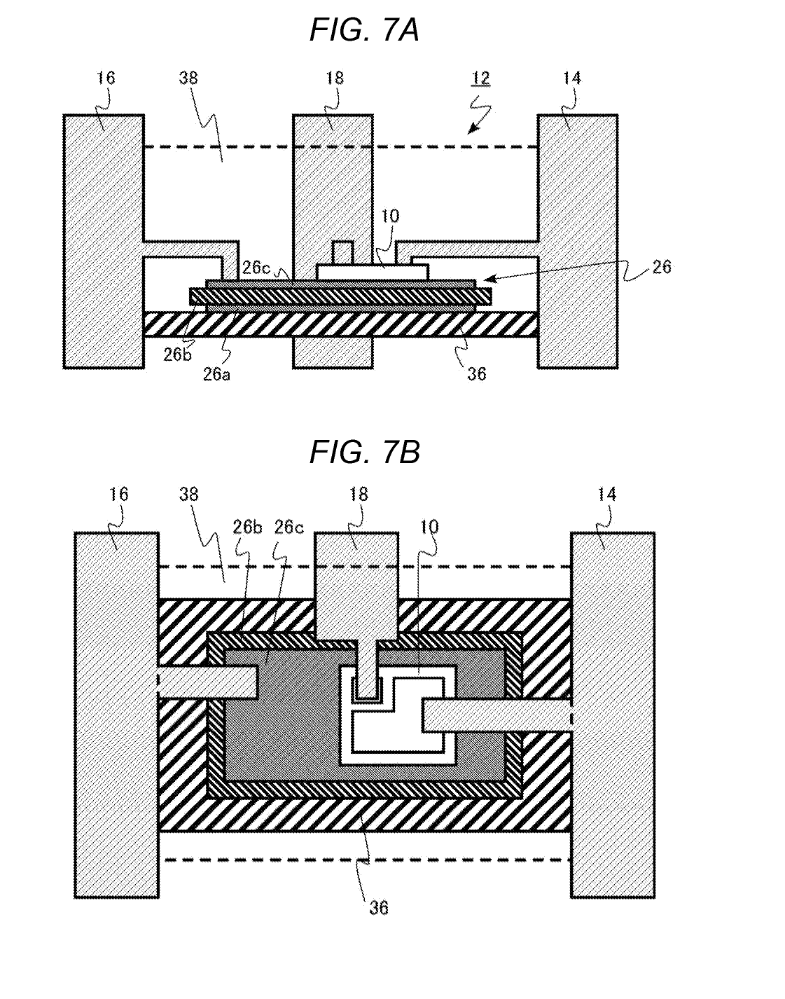

FIGS. 7A and 7B are schematic views of the semiconductor device according to the embodiment. FIG. 7A is a schematic cross-sectional view. FIG. 7B is a schematic top view. FIG. 7B is a view showing a state where the protective material on the upper part of the semiconductor chip is removed.

In the IGBTs according to the embodiment, the emitter terminal 14 is directly connected to the emitter electrode of the semiconductor chip 10 by an adhesive layer (not shown), the collector terminal 16 is directly connected with the conductive layer 26c by an adhesive layer (not shown), and the conductive layer 26c is connected with the collector electrode of the semiconductor chip 10, all within the volume of the resin protecting the semiconductor chip. The gate terminal 18 is directly connected with the gate electrode of the semiconductor chip 10 by an adhesive layer (not shown) within the volume of the resin protecting the semiconductor chip. The adhesive layer is conductive, for example, the adhesive layer is formed of solder.

The emitter, collector and gate terminals 14, 16 and 18 of the IGBTs according to the embodiment, similarly to the first embodiment, protrude from the upper surface, the lower surface, and the side surface of the package 12. Therefore when the plurality of IGBT's are mounted on a wiring substrate, the size of the resulting device is reduced.

In addition, compared to the second embodiment, a cross-sectional area of a region where a current flows is increased as each terminal is directly connected with electrodes of the semiconductor chip 10. Therefore, the resistance of the connections between the terminals and the semiconductor chip source, drain and gate is decreased, and the operation characteristics of the IGBTs are improved.

### Fourth Embodiment

The semiconductor device according to the embodiment is similar to the third embodiment except the fact that the semiconductor device has two terminals. Therefore, a part of the same description as the third embodiment will not be repeated.

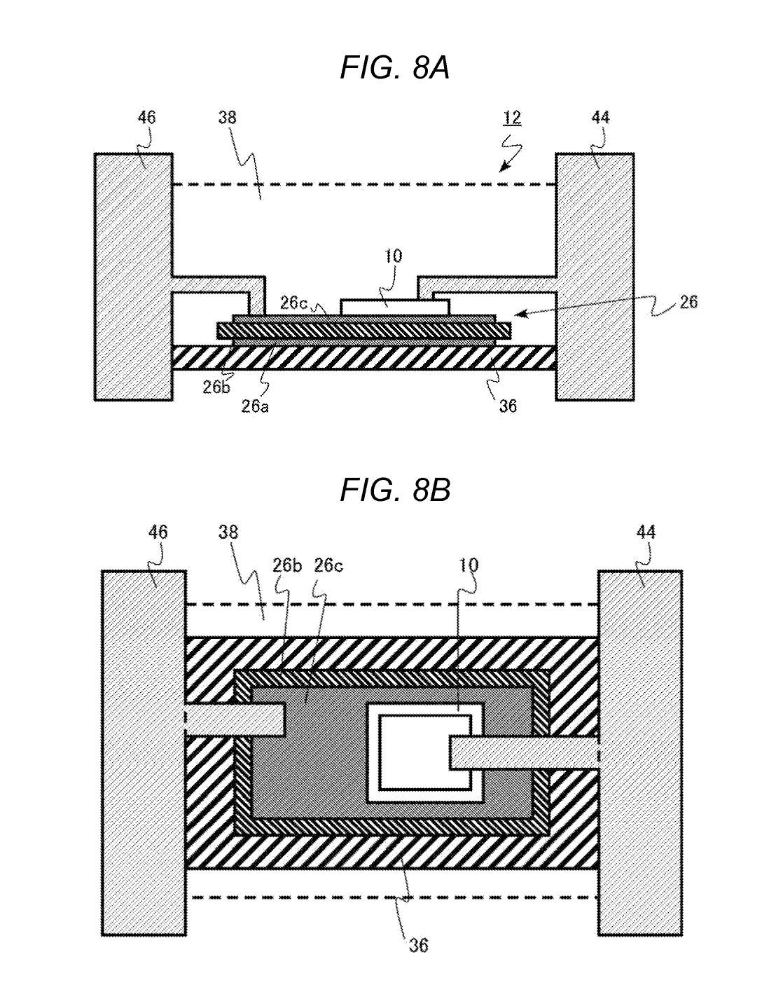

FIGS. 8A and 8B are schematic views of the semiconductor device according to the embodiment. FIG. 8A is a schematic cross-sectional view. FIG. 8B is a schematic top view. FIG. 8B is a view showing a state where the protective material on the upper part of the semiconductor chip is removed.

The semiconductor device according to the embodiment is, for example, a vertical diode with two terminals. The semiconductor device according to the embodiment includes the semiconductor chip 10, the package 12, an anode terminal (first electrode terminal) 44, and a cathode terminal (second electrode terminal) 46.

In the IGBT according to the embodiment, the anode terminal 44 is directly connected with an anode electrode of the semiconductor chip 10 by the adhesive layer (not shown). The cathode terminal 46 is directly connected with the conductive layer 26c by the adhesive layer (not shown). The conductive layer 26c is connected with the cathode electrode of the semiconductor chip 10. The adhesive layer has conductivity, for example, the adhesive layer is made of solder.

Each terminal of the diodes according to the embodiment, similarly to the third embodiment, protrudes from the upper surface, the lower surface, and the side surface of the package 12. Therefore, for example, when a semiconductor system in which a plurality of diodes are mounted on a wiring substrate, it is possible to reduce the size of the semiconductor system.

### Fifth Embodiment

The semiconductor device according to the embodiment is similar to the third embodiment except the fact that two semiconductor chips are provided in a single package. Therefore, a part of the same description as the third embodiment will not be repeated.

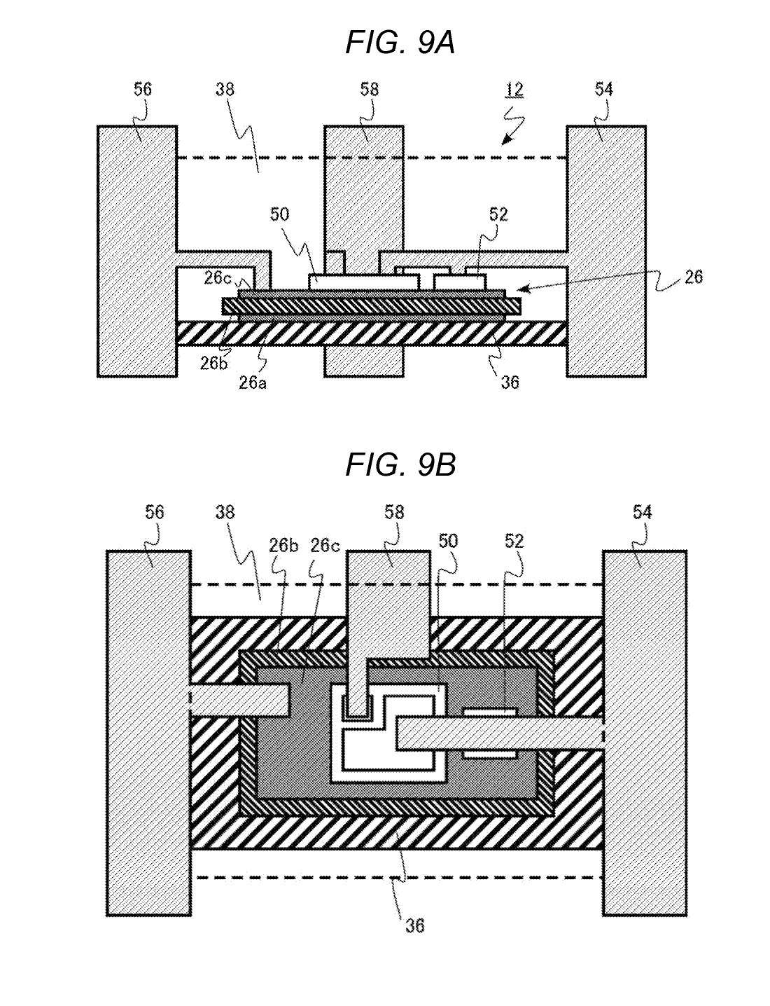

FIGS. 9A and 9B are schematic views of the semiconductor device according to the embodiment. FIG. 9A is a schematic cross-sectional view. FIG. 9B is a schematic top view. FIG. 9B is a view showing a state where the protective material on the upper part of the semiconductor chip is removed.

The semiconductor device according to the embodiment has, for example, a first semiconductor chip 50 and a second semiconductor chip 52. The first semiconductor chip 50 is, for example, a vertical IGBT with three terminals. The second semiconductor chip 52 is, for example, a vertical diode with two terminals which functions as a free-wheeling diode.

The semiconductor device according to the embodiment has a first electrode terminal 54, a second electrode terminal 56, and a gate terminal 58. The first electrode terminal 54 is a common terminal for the emitter terminal of the first semiconductor chip 50 and the anode terminal of the second semiconductor chip 52. The second electrode terminal 56 is a common terminal for the collector terminal of the first semiconductor chip 50 and the cathode terminal of the second semiconductor chip 52.

In the semiconductor device according to the embodiment, the first electrode terminal 54 is directly connected with the emitter electrode of the first semiconductor chip 50 and the anode electrode of the second semiconductor chip 52, by a conductive adhesive layer (not shown). In addition, the second electrode terminal 46 is directly connected with the conductive layer 26c by a conductive adhesive layer (not shown). The conductive layer 26c is connected with the collector electrode of the first semiconductor chip 50 and the cathode electrode of the second semiconductor chip 52. The adhesive layer is, for example, made of solder.

In the diodes according to the embodiment, similarly to the third embodiment, each terminal protrudes from the upper surface, the lower surface, and the side surface of the package 12. Therefore, for example, when the semiconductor system in which the plurality of semiconductor devices having two semiconductor chips of the IGBT and the diode is mounted on the printed circuit substrate is constructed, it is possible to make the size of the semiconductor system small.

In addition, the two semiconductor chips are not limited to the combination of the IGBT and the diode. For example, the two semiconductor chips can be another combination of a MOSFET and the diode, or the like. In addition, three or more semiconductor chips also can be provided in a single packaged device.

### Sixth Embodiment

The semiconductor device according to the embodiment is basically similar to the second embodiment except the fact that the semiconductor chip is formed not on the insulation substrate, but on a frame which is integrated with the electrode terminal. Therefore, a part of the same description as the second embodiment will not be repeated.

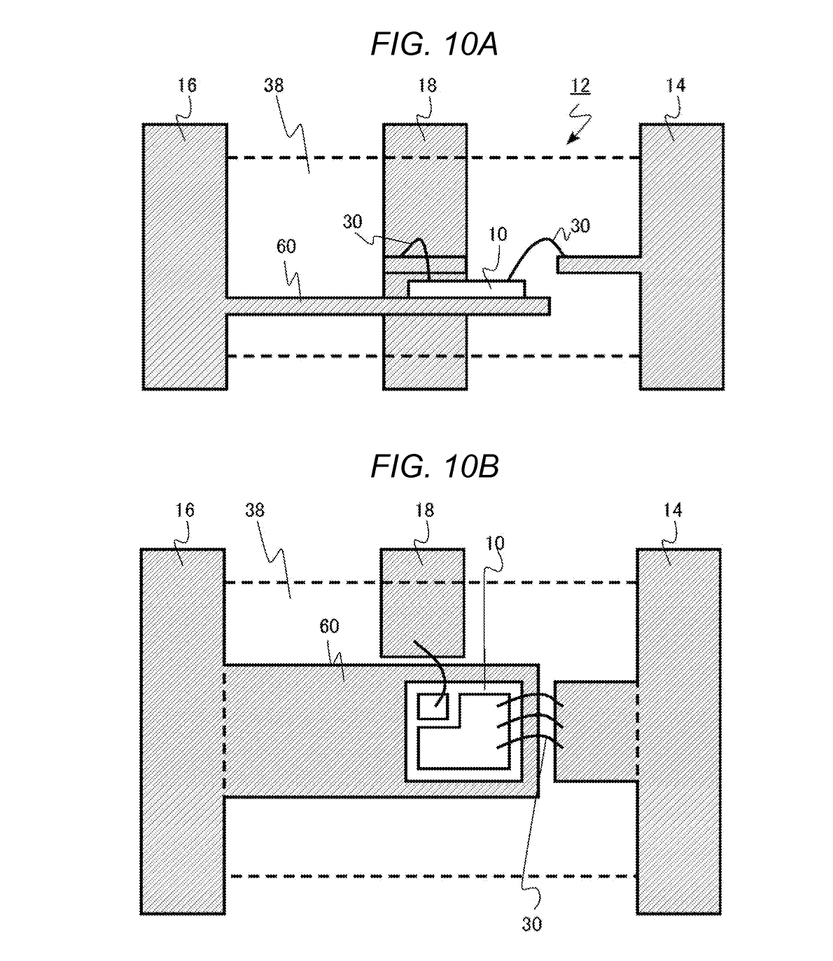

FIGS. 10A and 10B are schematic views of the semiconductor device according to the embodiment. FIG. 10A is a schematic cross-sectional view. FIG. 10B is a schematic top view. FIG. 10B is a view showing a state where the protective material on the upper part of the semiconductor chip is removed.

In the IGBTs according to the embodiment, the semiconductor chip 10 is mounted on a frame 60 which is integrally connected to the collector terminal 16 and is made of metal. The semiconductor chip 10 and the frame 60 are adhered together by a conductive adhesive layer (not shown), for example, with solder.

Each terminal of the IGBTs according to the embodiment, similarly to the second embodiment, protrudes from the upper surface, the lower surface, and the side surface of the package 12. Therefore, for example, when the semiconductor system in which the plurality of IGBTs is mounted on the print substrate is constructed, it is possible to make the size of the semiconductor system small.

In addition, compared to the second embodiment, use of smaller number of the components and easy manufacturing are possible.

### Seventh Embodiment

The semiconductor device according to the embodiment is similar to the second embodiment except the fact that the heat radiation plate is provided instead of the supporting substrate. Therefore, a part of the same description as the second embodiment will not be repeated.

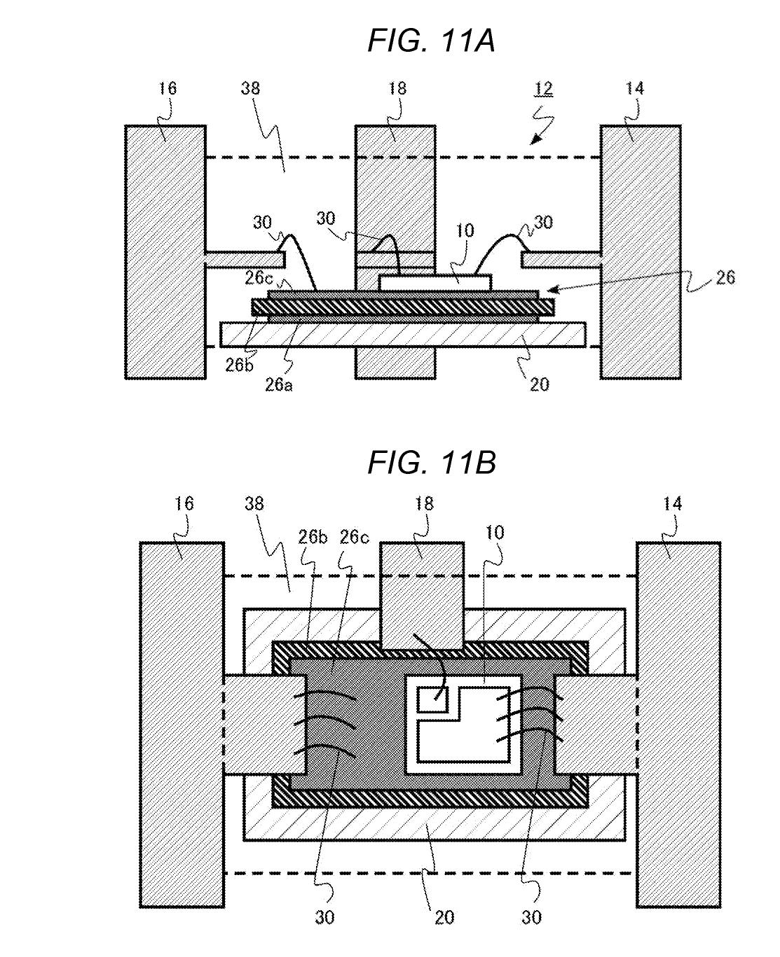

FIGS. 11A and 11B are schematic views of the semiconductor device according to the embodiment. FIG. 11A is a schematic cross-sectional view. FIG. 11B is a schematic top view. FIG. 11B is a view showing a state where the protective material on the upper part of the semiconductor chip is removed.

The IGBTs according to the embodiment has the heat radiation plate 20. On the heat radiation plate 20, the insulation substrate 26 is provided. The semiconductor chip 10 is mounted on the insulation substrate 26.

Each terminal of the IGBTs according to the embodiment, similarly to the second embodiment, protrudes from the upper surface, the lower surface, and the side surface of the package 12. Therefore, for example, when the semiconductor system in which the plurality of IGBTs is mounted on the print substrate is constructed, it is possible to make the size of the semiconductor system small.

The heat radiation plate 20 is provided, and thus heat dissipation is improved. Therefore, the semiconductor device with stable operation and high reliability is achieved.

### Eighth Embodiment

The semiconductor device according to the embodiment is similar to the modification example of the first embodiment except the fact that a recessed portion is provided on one side of an upper end or a lower end of the first and the second electrode terminals and a protruding portion is provided on the other side of an upper end or a lower end of the first electrode and second electrode terminals. The recessed portions and protruding portions are configured having matching profiles, such that a protruding portion of one terminal fits into the recessed portion of another terminal, enabling alignment of the terminals and greater surface area of the connection therebetween. The remainder of the device is basically unchanged from the modification example of the first embodiment, and the description of the first embodiment and the modification example will not be repeated.

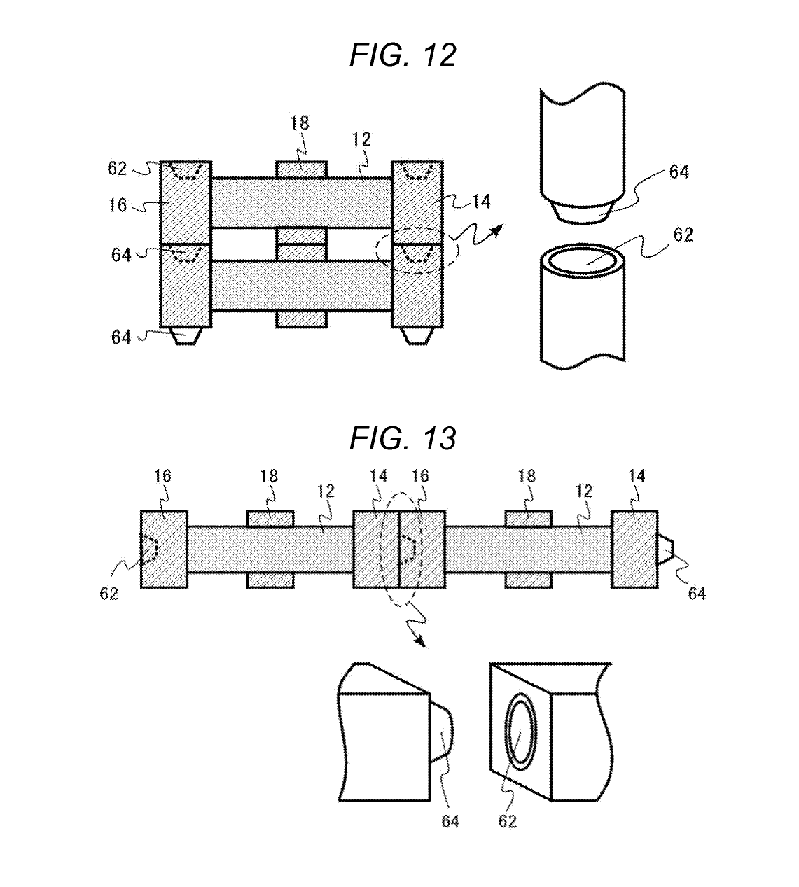

FIG. 12 is a schematic view of the semiconductor device according to the embodiment. FIG. 12 shows a configuration in which two semiconductor devices according to the embodiment are vertically laminated.

The semiconductor device according to the embodiment is, for example, a vertical IGBT with three terminals. The semiconductor device according to the embodiment includes the package 12 which has the semiconductor chip inside, the emitter terminal (first electrode terminal) 14, the collector terminal (second electrode terminal) 16, and the gate terminal (third electrode terminal) 18.

On each upper portion of the emitter terminal 14, the collector terminal 16, and the gate terminal 18, a recessed portion 62 is provided. On each lower portion of the emitter terminal 14, the collector terminal 16, and the gate terminal 18, a protruding portion 64 is provided. When the IGBTs are vertically stacked, the protruding portion 64 of each terminal of the IGBTs on the upper side is configured to fit within the recessed portion 62 of each terminal of the IGBTs on the lower side thereof

Each terminal of IGBTs according to the embodiment, similarly to the first embodiment, protrudes from the upper surface, the lower surface, and the side surface of the package 12. Therefore, for example, when the semiconductor system in which the plurality of IGBTs is mounted on the print substrate is constructed, it is possible to make the size of the semiconductor system small.

Furthermore, as a fitting configuration is provided in each terminal, it is possible to prevent misalignment when the plurality of IGBTs is vertically laminated. Therefore, the semiconductor system which can be easily manufactured and has stable characteristics is achieved.

### Ninth Embodiment

The semiconductor device according to the embodiment is similar to the first embodiment except the fact that a recessed portion is provided on one side of the first electrode terminal or the second electrode terminal and a protruding portion is provided on the other side of the first electrode terminal or the second electrode terminal.

FIG. 13 is a schematic view of the semiconductor device according to the embodiment. FIG. 13 shows a configuration in which two semiconductor devices of the embodiment are horizontally arranged.

The semiconductor device according to the embodiment is, for example, a vertical IGBT with three terminals. The semiconductor device according to the embodiment includes the package 12 which has the semiconductor chip inside, the emitter terminal (first electrode terminal) 14, the collector terminal (second electrode terminal) 16, and the gate terminal (third electrode terminal) 18.

The recessed portion 62 is provided on the side surface of the collector terminal 16, and a mating protruding portion 64 is provided on the side surface of the emitter terminal 14. When the IGBTs are horizontally arranged side by side, the protruding portion 64 of the emitter terminal 14 of one IGBT is received within the recessed portion 62 of the collector terminal 16 of the other IGBT.

Each terminal of the IGBTs according to the embodiment, similarly to the first embodiment, protrudes from the upper surface, the lower surface, and the side surface of the package 12. Therefore, for example, when the semiconductor system in which the plurality of IGBTs is mounted on the print substrate is constructed, it is possible to make the size of the semiconductor system small.

Furthermore, as the fitting structure is provided on the side surface of the terminal, it is possible to prevent misalignment when the plurality of IGBTs is horizontally arranged. Therefore, the semiconductor system which can be easily manufactured and has stable characteristics is achieved.

### Tenth Embodiment

The semiconductor device according to the embodiment is similar to the modification example of the first embodiment except the fact that a threaded hole is provided on the upper end and the lower end of the first electrode terminal, and a threaded hole is provided on the upper end and the lower end of the second electrode terminal.

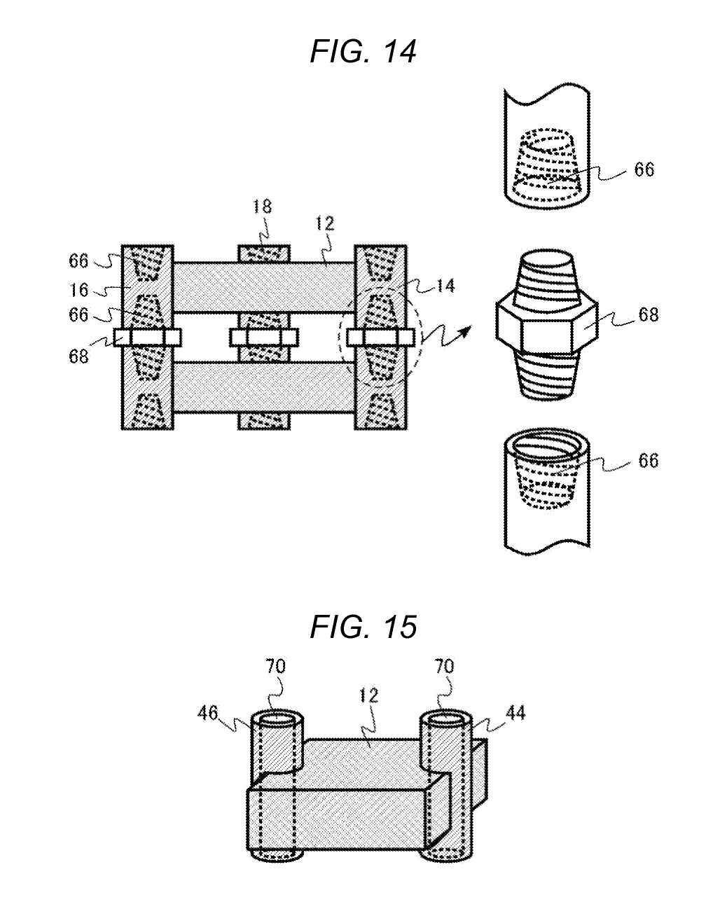

FIG. 14 is a schematic view of the semiconductor device according to the embodiment. FIG. 14 shows a configuration in which two semiconductor devices are vertically laminated.

The semiconductor device according to the embodiment is, for example, a vertical IGBT with three terminals. The semiconductor device according to the embodiment includes the package 12 which has the semiconductor chip inside, the emitter terminal (first electrode terminal) 14, the collector terminal (second electrode terminal) 16, and the gate terminal (third electrode terminal) 18.

On each upper end and lower end of the emitter terminal 14, the collector terminal 16, and the gate terminal 18, a threaded hole 66 is provided. The thread direction is reversed between the upper end hole 66 and the lower end hole 66, such that a threaded fastener having the same thread pitch is received in a hole in the upper end of a terminal of one IGBT and the lower end of a terminal of another IGBT, rotation of the fastener in a first direction draws the IGBT's together, and rotation is the opposite direction causes the IGBT's to move away from each other. When the IGBTs are vertically laminated, a threaded fastener 68 is inserted between the threaded hole 66 of each terminal of the IGBTs on the upper side and the threaded hole 66 of each terminal of the IGBTs on the lower side. The upper IGBT and the lower IGBT are fixed together by appropriate rotation of the bolt 68.

Each terminal of the IGBTs according to the embodiment, similarly to the first embodiment, protrudes from the upper surface, the lower surface, and the side surface of the package 12. Therefore, for example, when the semiconductor system in which the plurality of IGBTs is mounted on the print substrate is constructed, it is possible to make the size of the semiconductor system small.

Furthermore, the threaded holes 66 are provided in each terminal, and the upper IGBT and the lower IGBT can be fixed together via the bolts 68. Therefore, it is possible to prevent misalignment and separation when the plurality of IGBTs is vertically laminated. Therefore, the semiconductor system which can be easily manufactured and has stable characteristics is achieved.

### Eleventh Embodiment

The semiconductor device according to the embodiment is basically similar to the fourth embodiment except the fact that the first electrode terminal and the second electrode terminal have a through-hole which extends from the upper end to the lower end of the electrode terminal, i.e., it extends through each terminal.

FIG. 15 is a schematic perspective view of the semiconductor device according to the embodiment. The semiconductor device according to the embodiment is, for example, a vertical diode with two terminals. The semiconductor device according to the embodiment includes the package 12 which has the semiconductor chip inside, the anode terminal (first electrode terminal) 44, and the cathode terminal (second electrode terminal) 46.

The anode terminal 44 and the cathode terminal 46 have a cylindrical shape. In the anode terminal 44, a through-hole 70 which extends from the upper end to the lower end of the terminal 44 is provided. In the cathode terminal 46, a through-hole 70 which extends from the upper end to the lower end of the terminal 46 is provided. In addition, the anode terminal 44 and the cathode terminal 46 can have a prism shape other than a cylindrical shape.

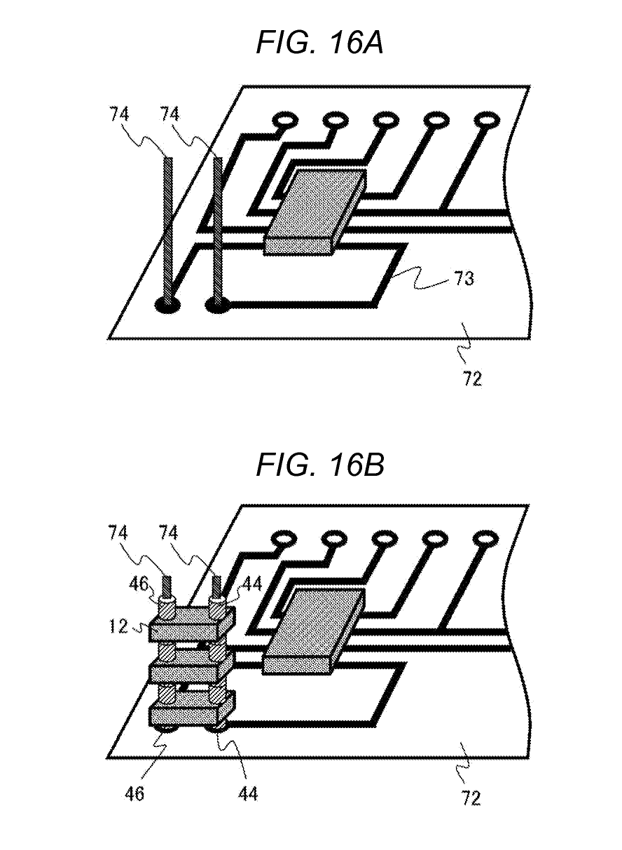

FIGS. 16A and 16B are schematic perspective views of the semiconductor system including the semiconductor devices according to the embodiment. FIG. 16A is a configuration diagram of the printed circuit substrate having printed wiring circuit 73 thereon. FIG. 16B is a configuration diagram when the semiconductor device according to the embodiment is mounted on the print substrate.

As shown in FIG. 16A, on the print substrate 72, a pair of supports bar 74 are provided in order to mount the semiconductor device according to the embodiment. Each support bar 74 is, for example, electrically connected to the printed wiring 73 on the substrate. As shown in FIG. 16B, the support bars 74 penetrate the through-holes 70 of the terminals of each diode, and thus in this embodiment three diodes are vertically laminated. In this configuration, the three diodes are mounted on the print substrate in parallel.

The support bar 74 is made of, for example, metal. In addition, each terminal of the support bar 74 and the diode are connected to each other, for example, by soldering.

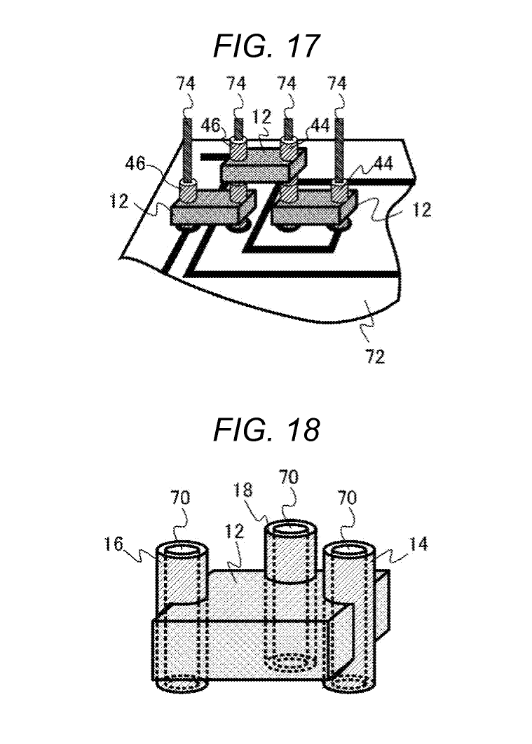

FIG. 17 is an additional schematic perspective view of the semiconductor system which includes the semiconductor device according to the embodiment. FIG. 17 is a configuration diagram when the semiconductor device of the embodiment is mounted on the print substrate.

As shown in FIG. 17, the support bars 74 penetrate the through-holes 70 of the terminals of each diode, and thus the three diodes are vertically or horizontally disposed. According to the configuration, the three diodes are mounted on the print substrate 72 in series.

Each terminal of the diodes according to the embodiment protrudes from the upper surface and the lower surface of the package 12, and thus when the plurality of diodes are vertically laminated, the additional connection wiring is not required, and it is possible that each terminal of the diodes are connected with each other. In addition, as shown in FIGS. 16A and 16B and in FIG. 17, it is possible to dispose diodes in three dimensions. Therefore, for example, when the semiconductor system in which the plurality of diodes is mounted on the print substrate is constructed, it is possible to make the size of the semiconductor system small.

In addition, when the diodes are vertically or horizontally disposed, the number of diodes is appropriately chosen. By doing this, it is possible to easily set a rated value to a predetermined value. Therefore, the degree of design freedom of the semiconductor system is improved.

Furthermore, as through-holes 70 are provided in each terminal, it is possible to prevent misalignment when the plurality of diodes is vertically stacked. Therefore, the semiconductor system easy to manufacture and having stable characteristics is achieved.

### Twelfth Embodiment

The semiconductor device according to the embodiment is similar to the modification example of the eleventh embodiment except the fact that three terminals are provided instead of two terminals.

FIG. 18 is a schematic perspective view of the semiconductor device according to the embodiment. The semiconductor device according to the embodiment is, for example, a vertical IGBT with three terminals. The semiconductor device according to the embodiment includes the package 12 which has the semiconductor chip inside, the emitter terminal (first electrode terminal) 14, the collector terminal (second electrode terminal) 16, and the gate terminal (third electrode terminal) 18.

The emitter terminal 14, the collector terminal 16, and the gate terminal 18 have a cylindrical shape. In the emitter terminal 14, the collector terminal 16, and the gate terminal 18, a through-hole 70 extends from the upper end to the lower end of the terminal. In addition, the emitter terminal 14, the collector terminal 16, and the gate terminal 18 can have a prism (triangular, rectangular, pentagonal, hexagonal, etc., in cross section) shape other than a circular cylindrical shape.

Each terminal of the IGBTs according to the embodiment protrudes from the upper surface and the lower surface of the package 12, and thus when the plurality of IGBTs are vertically stacked, and additional connection wiring is not required, and it is possible that each terminal of the IGBTs are connected with each other. In addition, it is possible to dispose IGBTs in three dimensions. Therefore, for example, when the semiconductor system in which the plurality of IGBTs is mounted on the print substrate is constructed, it is possible to make the size of the semiconductor system small.

In addition, when the IGBTs are vertically or horizontally arranged, the number of IGBT is appropriately chosen. By doing this, it is possible to easily set a rated value to a predetermined value. Therefore, the degree of design freedom of the semiconductor system is improved.

Furthermore, as a through-hole 70 is provided in each terminal, it is possible to prevent misalignment when the plurality of IGBTs is vertically laminated. Therefore, the semiconductor system having an easy manufacture and stable characteristics is achieved.

### Thirteenth Embodiment

The semiconductor device according to the embodiment is basically similar to the eleventh embodiment except the fact that the diodes are connected with a semiconductor module.

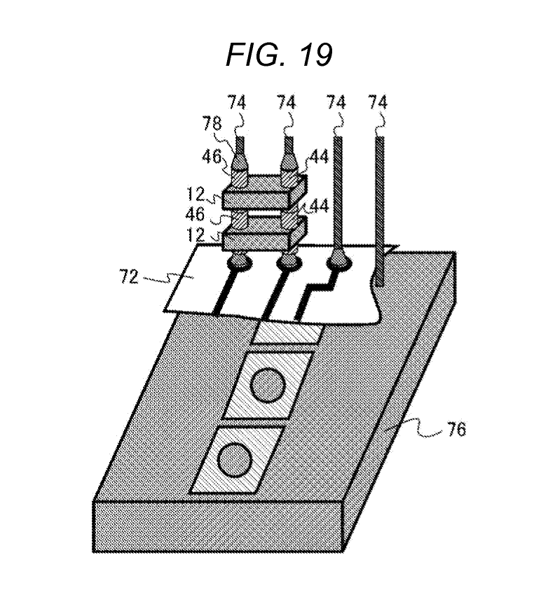

FIG. 19 is a schematic perspective view of the semiconductor system which includes the semiconductor devices according to the embodiment. As shown in FIG. 19, a terminal of a semiconductor module 76 includes support bars 74 having a mating shape to the through holes in the first and second terminals of a diode. The semiconductor module 76 is, for example, a module used for high electric power applications. In addition, for example, a signal terminal of the semiconductor module 76 has the support bar 74 electrically connected therewith. On the printed circuit substrate 72, the support bar 74 is provided in order to mount and electrically connect the semiconductor devices into the module according to the embodiment.

As shown in FIG. 19, the support bars 74 penetrate the through-holes 70 of the terminals of each diode, and thus in this example two diodes are vertically stacked and connected. According to the configuration, the two diodes are mounted on the signal terminal of the semiconductor module 76 in parallel.

The support bar 74 is made of, for example, metal. In addition, each terminal of the support bar 74 and the diode are connected to each other, for example, by soldering 78.

In addition, FIG. 19 shows an example when the printed circuit substrate 72 is interposed between the semiconductor module 76 and each diode. It is also possible to have a configuration in which the printed circuit substrate 72 is omitted.

Each terminal of the diodes according to the embodiment protrudes from the upper surface and the lower surface of the package 12, and thus when the plurality of diodes are vertically laminated, additional connection wiring is not required, and it is possible that each terminal of the diodes are connected with each other. In addition, it is possible to dispose diodes in three dimensions. Therefore, for example, when the semiconductor system in which the plurality of diodes is mounted on the semiconductor module is constructed, it is possible to make the size of the semiconductor system small.

In addition, when the diodes are vertically or horizontally arranged, the number of diodes is appropriately chosen. By doing this, it is possible to easily set a rated value to a predetermined value. Therefore, the degree of design freedom of the semiconductor system is improved.

Furthermore, as through-holes 70 are provided in each terminal, it is possible to prevent misalignment when the plurality of diodes is vertically laminated. Therefore, the semiconductor system having an easy manufacture and stable characteristics is achieved.

### Modification Example

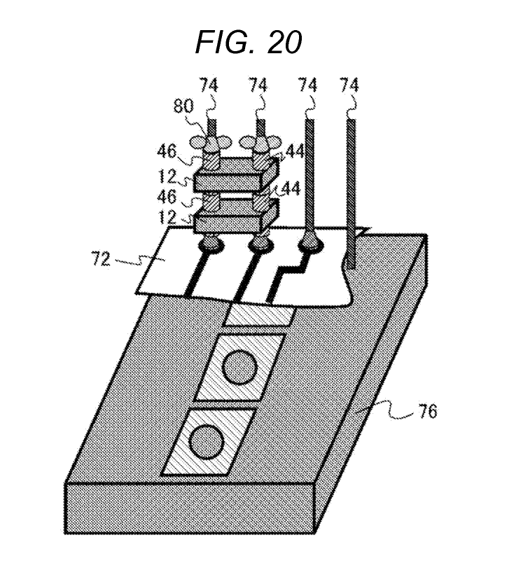

FIG. 20 is a schematic perspective view of the modification example of the semiconductor system which includes the semiconductor device according to the embodiment. Each diode is fixed on the support bar 74 not by soldering, but by using a thumbscrew 80. In this embodiment, the support bars 74 are threaded, and an internally threaded thumbscrew 80 is rotated over the threaded support bars to squeeze the diodes together and against appropriate circuit traces on the printed circuit substrate to electrically connect, and physically secure, the diodes thereon. According to the modification example, it is possible to easily fix the diode to the semiconductor module 76.

### Fourteenth Embodiment

According to the embodiment, in the semiconductor system, the diode or the IGBT is mounted on the print substrate, and a converter circuit or an inverter circuit is provided. The diode or the IGBT in the embodiment is similar to the eleventh or the twelfth embodiment.

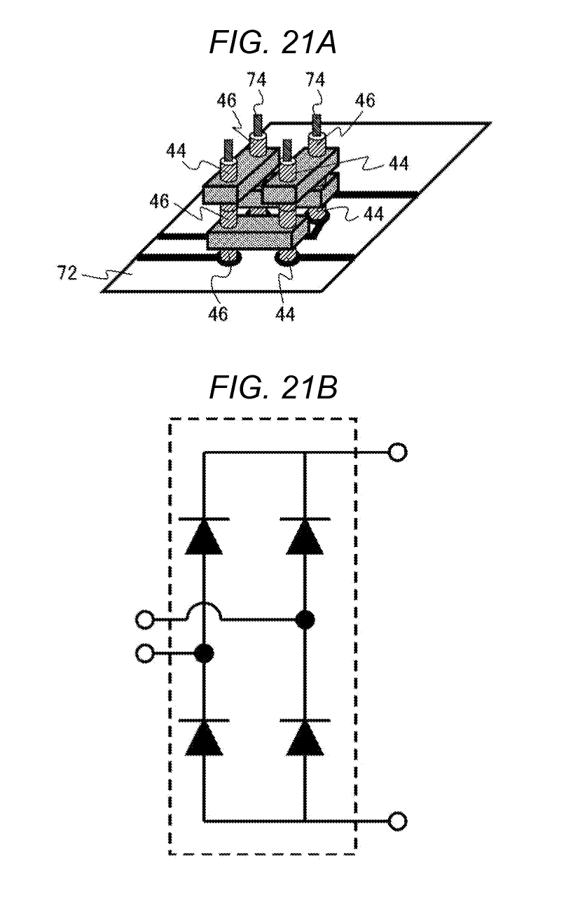

FIGS. 21A and 21B are schematic views of the semiconductor system according to the embodiment. FIG. 21A is a schematic perspective view of the semiconductor system according to the embodiment. FIG. 21B is a circuit diagram of the FIG. 21A. The semiconductor system according to the embodiment includes the converter circuit.

In the semiconductor system according to the embodiment, four diodes (semiconductor device) are vertically and horizontally arranged on the print substrate 72, and fixed to the support bar 74. Each diode according to the embodiment has the package 12 which has the semiconductor chip inside, the anode terminal (first electrode terminal) 44, and the cathode terminal (second electrode terminal) 46.

Each diode is arranged as shown in FIG. 21A, and thus the semiconductor system which includes the converter circuit is achieved as shown in FIG. 21B.

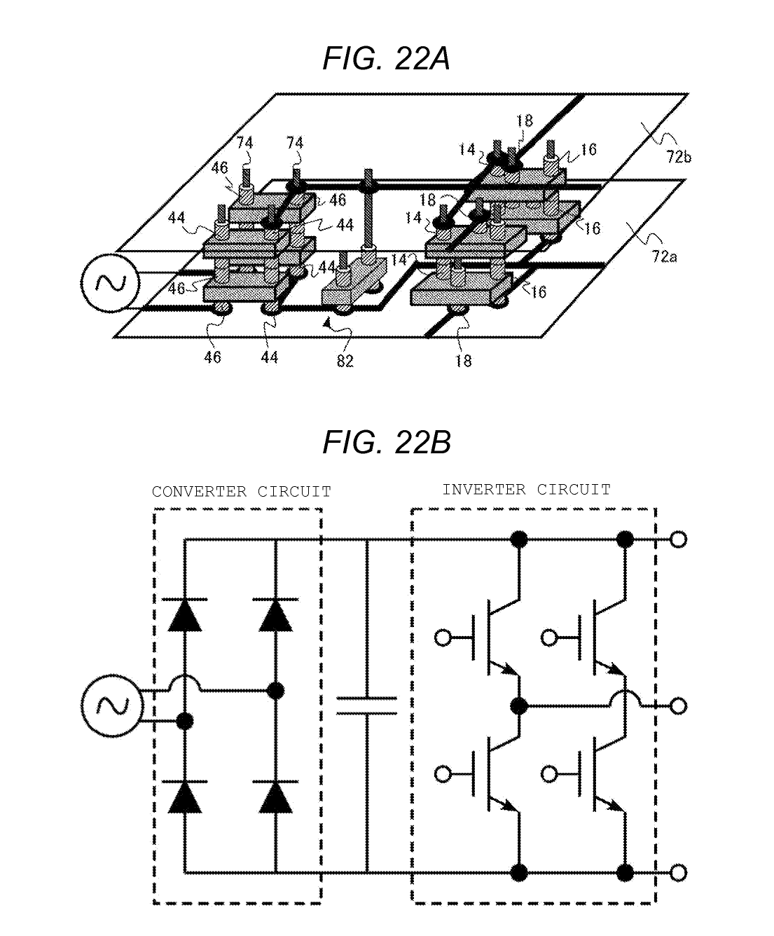

FIGS. 22A and 22B are schematic views of the semiconductor system according to the embodiment. FIG. 22A is a schematic perspective view of the semiconductor system according to the embodiment. FIG. 22B is a circuit diagram of the configuration shown in FIG. 22A. The semiconductor system according to the embodiment includes the converter circuit and the inverter circuit.

The semiconductor system according to the embodiment is configured to have four diodes, four IGBTs, and one capacitor 82 which are mounted in three dimensions by using a lower portion print substrate 72a and an upper portion print substrate 72b. Each diode according to the embodiment has the anode terminal 44 and the cathode terminal 46. Each IGBT according to the embodiment has the emitter terminal 14, the collector terminal 16, and the gate terminal 18.

Each of the diodes, IGBTs, and the capacitor 82 are disposed as shown in FIG. 22A, and thus the semiconductor system which includes the converter circuit and the inverter circuit is achieved as shown in FIG. 22B.

In the semiconductor system according to the embodiment, the semiconductor devices, such as the diodes or the IGBT, are disposed in three dimensions without using additional connection wiring. Therefore, it is possible to make the size of the semiconductor system small.

In addition, when the semiconductor devices are vertically or horizontally disposed, the number of semiconductor devices is appropriately chosen. By doing this, it is possible to easily set a rated value to a predetermined value. Therefore, the degree of design freedom of the semiconductor system is improved.

Furthermore, as a through-hole 70 is provided in each terminal, it is possible to prevent misalignment when the plurality of diodes or IGBTs is vertically laminated. Therefore, the semiconductor system having an easy manufacture and stable characteristics is achieved.

In the embodiment, the vertical IGBT and the vertical diode are described as examples of the semiconductor device. However, it is possible to adopt a device, for example, a vertical metal oxide semiconductor field effect transistor (MOSFET) having a source terminal, a drain terminal, and the gate terminal, and a vertical thyristor, other than the vertical IGBT or diode. In addition, it is also possible to adopt the embodiment to a horizontal device which has the electrode on the only one of the surfaces on the upper portion or the lower portion of the semiconductor device.

In the embodiment, a device using silicon is described as an example of a semiconductor. However, the embodiment is not limited to silicon, and it is possible to adopt a carbide semiconductor, such as SiC, and a nitride semiconductor, such as GaN-based semiconductor.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein maybe made without departing from the spirit of the inventions. The accompanying claims and their equivalents are intended to cover such forms or modifications as would fall within the scope and spirit of the inventions.

What is claimed is:

1. A semiconductor device, comprising:
a semiconductor chip;
a package that surrounds the semiconductor chip, the package including a first surface, a second surface, and at least opposed side surfaces extending between the first surface and the second surface;
a first electrode terminal of which a first end portion thereof is exposed at the first surface of the package, and of which a second portion thereof opposed to the first end portion is exposed at the second surface of the package; and
a second electrode terminal of which a first end portion thereof is exposed at the first surface of the package, and of which a second end portion thereof opposed to the first end portion is exposed at the second surface of the package.

2. The device according to claim 1, wherein
the first electrode terminal and the second electrode terminal are exposed at opposed side surfaces of the package.

3. The device according to claim 1, wherein
The opposed end portions of first and second terminals extend outwardly of the first and second surfaces of the package

4. The device according to claim 1, wherein:
a recess extends inwardly of one of a first end and a second end of the first electrode terminal, and a protrusion extends outwardly of the other of a first end and a second end of the first electrode terminal, and
a recess extends inwardly of one of a first end and a second end of the second electrode terminal, and a protrusion extends outwardly of the other of a first upper end and a second end of the second electrode terminal.

5. The device according to claim 4, wherein the profile of the wall of the recess and the profile of the wall of the protrusion are the same profile.

6. The device according to claim 1, wherein
a through-hole extends through each of the first electrode terminal and the second electrode terminal, and opens at the first end and the second end of the terminals.

7. The device according to claim 1,
wherein the package is made of resin.

8. The device according to claim 1, wherein the package comprises:
a case surrounding the semiconductor chip and having open opposed first and second sides;
a cap disposed over, and sealing, the first side of the resin cap;
a support plate disposed over, and sealing, the second side of the resin cap.

9. The device according to claim 8, wherein the first terminal and second terminal further extend outwardly of the sides of the package.

10. The device according to claim 1, further including a third terminal having opposed ends thereof exposed at the first and second surfaces of the package, and further exposed at a third side surface of the package extending between the opposed side surfaces and the first and second surfaces.

11. The device according to claim 1, wherein the opposed ends of at least one of the first and second terminals include a threaded hole extending therein.

12. A semiconductor system, comprising:
a printed circuit board;
at least a first and a second packaged semiconductor device, each packaged semiconductor device comprising;
a semiconductor chip;
a packaging that surrounds the semiconductor chip, the packaging including a first surface, a second surface, and at least opposed side surfaces extending between the first surface and the second surface;
a first electrode terminal of which a first end portion thereof is exposed at the first surface of the packaging, and of which a second portion thereof opposed to the first end portion is exposed at the second surface of the packaging; and
a second electrode terminal of which an first end portion thereof is exposed at the first surface of the, and of which a second end portion thereof opposed to the first end portion is exposed at the lower surface of the package; wherein
an end surface of at least one of the first and second electrode terminals of the first packaged semiconductor device electrically contacting a surface of the printed circuit board; and
at least one of the first and second electrode terminals of the second packaged semiconductor device in electrical contact with one of the first and second terminals of the first packaged semiconductor device.

13. The semiconductor system of claim 12, wherein an end surface of the first terminal of the first packaged semiconductor device not in contact with the printed circuit board is in electrical contact with the end surface of the first terminal of the second packaged semiconductor device.

14. The semiconductor system of claim 12, wherein an end surface of the first terminal of the first packaged semiconductor device not in contact with the printed circuit board is in electrical contact with the end surface of the second terminal of the second packaged semiconductor device.

15. The semiconductor system of claim 12, wherein each of the first and second terminals include a hole extending therethrough and exiting the opposed end surfaces thereof, and a plurality of rods extend outwardly of, and in electrical communication with, the printed circuit board; wherein
at least one of the rods extend through a through hole of at least one of the first and second terminals of each of the first and the second semiconductor devices.

16. The semiconductor system of claim 15, wherein one rod extends through the through hole in the first terminal of each of the first and second packaged semiconductor devices, and a second rod extends through the through hole in the second terminal of each of the first and second packaged semiconductor devices.

17. A method of interconnecting packaged semiconductor devices, at least two semiconductor devices having a packaging, a semiconductor chip disposed within the packaging, and a first terminal in electrical contact with a first functional area of the chip and exposed outwardly of packaging and a second terminal in electrical contact with a second functional area of the chip and exposed outwardly of the packaging; including the steps of:
locating a first packaged semiconductor device adjacent to the second semiconductor device, and electrically connecting one of the first and second terminals of the first semiconductor device to one of the first and second terminals of the second semiconductor device.

18. The method of claim 17, wherein the step of connecting one of the first and second terminals of the first semiconductor device to one of the first and second terminals of the second semiconductor device comprises;
providing a hole extending through opposed end faces of the first and second terminals of the semiconductor device;
extending a rod through the hole in one of the first and second terminals of the first semiconductor device and into one of the first and second terminals of the second semiconductor device; and
providing a conductive path between the hole and the rod.

19. The method of claim 17, wherein the step of connecting one of the first and second terminals of the first semiconductor device to one of the first and second terminals of the second semiconductor device comprises;
providing a threaded hole extending inwardly of opposed end faces of the first and second terminals of the first and second semiconductor devices, the direction of the threads in the hole at the first end of the terminal extending in a opposed direction to that of the threads in the second hole;
providing a fastener having a first threaded projection and a second threaded projection opposed to the first threaded projection, the direction of the threads on the first threaded projection extending in a opposed direction to that of the threads in the second threaded projection;
extending the first threaded projections into openings in a first end face of the first terminal of the first and second semiconductor devices and extending the second threaded projections into openings in a first end face of the second terminal of the first and second semiconductor devices; and
rotating the fastener to draw the first and second semiconductor devices together.

20. The method of claim 17, wherein the step of connecting one of the first and second terminals of the first semiconductor device to one of the first and second terminals of the second semiconductor device comprises;
providing an opening having an opening profile extending inwardly of one of the opposed end faces of the first and second terminals of the first and second semiconductor devices;
providing a projection having a projection profile matching the opening profile extending outwardly of the other one of the opposed end faces of the first and second terminals of the first and second semiconductor devices;
positioning a projection of the first terminal of the first semiconductor device inwardly of an opening of one of the first and second terminals of the second semiconductor device.
